(19) United States
(12) Patent Application Publication
(10) Pub. No.: US 2016/0225715 A1
(43) Pub. Date: Aug. 4, 2016

(54) MICROELECTRONIC TRANSISTOR CONTACTS AND METHODS OF FABRICATING THE SAME

(71) Applicants: Anthony ST. AMOUR, Portland, OR (US); Joseph STEIGERWALD, Forest Grove, OR (US); INTEL CORPORATION, Santa Clara, CA (US)

(72) Inventors: Anthony St. Amour, Portland, OR (US); Joseph Steigerwald, Forest Grove, OR (US)

(73) Assignee: INTEL CORPORATION, Santa Clara, CA (US)

(21) Appl. No.: 15/022,434

(22) PCT Filed: Nov. 20, 2013
(86) PCT No.: PCT/US13/70923

§ 371 Date: Mar. 16, 2016

(51) Int. Cl. H01L 23/535; H01L 23/528; H01L 23/532; H01L 21/768

(52) U.S. Cl. CPC H01L 23/535; H01L 21/76805; H01L 21/76831; H01L 21/76846; H01L 21/76895; H01L 23/5283; H01L 23/53266; H01L 2221/1063

(57) ABSTRACT

A transistor contact of the present description may be fabricated by forming a via through an interlayer dielectric layer disposed on a microelectronic substrate, wherein the via extends from a first surface of the interlayer dielectric layer to the microelectronic substrate forming a via sidewall and exposing a portion of the microelectronic substrate. A conformal contact material layer may then be formed adjacent the exposed portion of the microelectronic substrate, the at least one via sidewall, and the interlayer dielectric first surface. An etch block plug formed within the via proximate the microelectronic substrate. The contact material layer not protected by the etch block plug may be removed followed by the removal of the etch block plug and the filling the via with a conductive material.

### TECHNICAL FIELD

Embodiments of the present description generally relate to the field of microelectronic devices, and, more particularly, to source/drain contacts for microelectronic transistors.

### BACKGROUND

Higher performance, lower cost, increased miniaturization of integrated circuit components, and greater packaging density of integrated circuits are ongoing goals of the microelectronic industry for the fabrication of microelectronic devices. As these goals are achieved, the microelectronic devices scale down, i.e. become smaller, which increases the need for optimal performance from each integrated circuit component. One area of potential performance enhancement is resistance reduction in source/drain contacts.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIGS. 1-10 are side cross-sectional views of a process of forming a source/drain contact for a microelectronic transistor, according to an embodiment of the present description.

FIGS. 11 and 12 are side cross-sectional views of forming a source/drain contact for a microelectronic transistor, according to another embodiment of the present description.

FIG. 13 is a flow chart of a process of fabricating a nanowire transistor, according to an embodiment of the present description.

FIG. 14 illustrates a computing device in accordance with one implementation of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Embodiments of the present description include source/drain contacts (also referred to as “transistor contacts”) for a microelectronic transistor which have an increased volume of conductive material used to form the transistor contact, which may reduce the electrical resistance thereof, and includes process of forming the transistor contacts, which may relax the constraints on material choices and on downstream processing relative to the known fabrication processes. Such a transistor contact may be fabricated by forming a via through an interlayer dielectric layer disposed on a microelectronic substrate, wherein the via extends from a first surface of the interlayer dielectric layer to the microelectronic substrate forming a via sidewall and exposing a portion of the microelectronic substrate. A contact material layer may then be formed adjacent the exposed portion of the microelectronic substrate, the at least one via sidewall, and the interlayer dielectric first surface. An etch block plug may be formed within the via proximate the microelectronic substrate. The contact material layer not protected by the etch block plug may be removed followed by the removal of the etch block plug and filling the via with a conductive material.

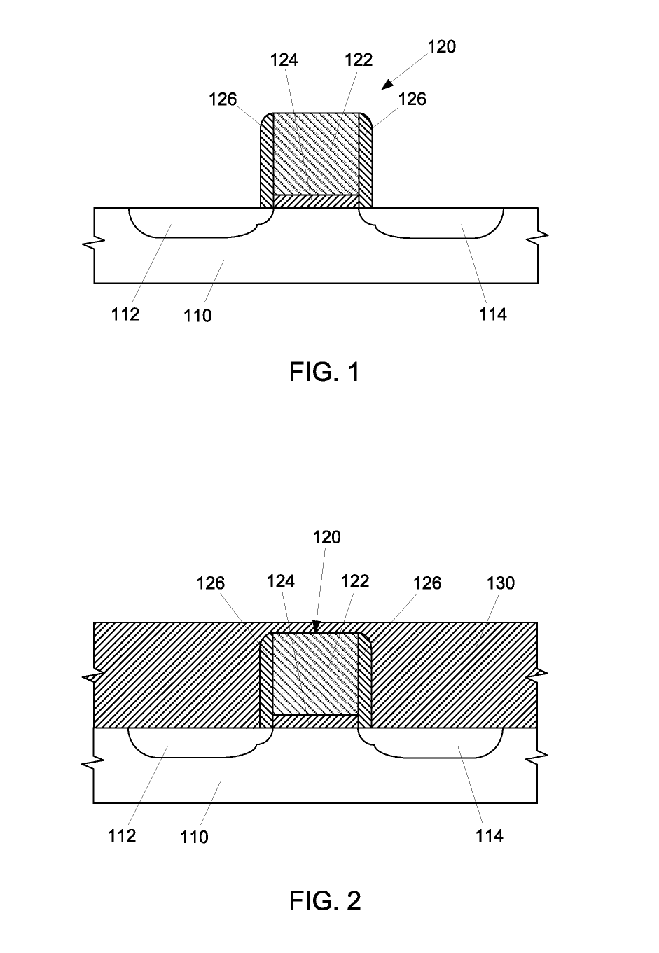

FIGS. 1-10 illustrate a method of forming source/drain contacts (also referred to as “transistor contacts”) for a microelectronic transistor. For the sake of conciseness and clarity, a single microelectronic transistor will be illustrated. As illustrated in FIG. 1, a microelectronic substrate 110 may be provided or formed from any suitable material. In one embodiment, the microelectronic substrate 110 may be a bulk substrate composed of a single crystal of a material which may include, but is not limited to, silicon, germanium, silicon-germanium or a III-V compound semiconductor material. In other embodiments, the microelectronic substrate 110 may comprise a silicon-on-insulator substrate (SOI), wherein an upper insulator layer composed of a material which may include, but is not limited to, silicon dioxide, silicon nitride or silicon oxy-nitride, disposed on the bulk substrate. Alternatively, the microelectronic substrate 110 may be formed directly from a bulk substrate and local oxidation is used to form electrically insulative portions in place of the above described upper insulator layer. In yet another embodiment, FIG. 1 may illustrate a cross-sectional view of a non-planar transistor, such as a FinFET or tri-gate transistor, where microelectronic substrate 110 may be a three-dimensional fin structure composed of a single crystal material. In such an embodiment, the cross-sectional view shown in FIG. 1 is taken along the length of the fin 110 and fine 110 includes a top surface as well as two laterally opposing sidewall surfaces.

As further shown in FIG. 1, a transistor gate 120 may be formed on the microelectronic substrate 110. The transistor gate 120 may include a gate electrode 122 with a gate dielectric 124 disposed between the gate electrode 122 and the microelectronic substrate 110. The transistor gate 120 may further include dielectric spacers 126 formed on opposing sides of the gate electrode 122. A source region 112 and a drain region 114 may be formed in the microelectronic substrate 110, such as by ion implantation of appropriate dopants, on opposing sides of the transistor gate 120. The functions and fabrication processes for the components of the transistor gate 120, the source region 112, and the drain region 114 are well known in the art and for the sake of conciseness and clarity will not be discussed herein. In embodiments of the invention where the microelectronic substrate 110 is a three-dimensional fin structure, the gate dielectric 124 may be formed on the top surface and on the laterally opposing sidewall surfaces of the three-dimensional fin structure while the gate electrode 122 may be formed on the gate dielectric 124 located on the top surface of the fin structure and adjacent the gate dielectric 124 located on the laterally opposing sidewall surfaces. In such an embodiment, the dielectric spacers 126 may also be formed on the top surface and on the laterally opposing sidewall surfaces of the fin structure. The source region 112 and the drain region 114 are formed within the fin structure as is well known in the art.

The gate dielectric 124 may comprise any appropriate dielectric material. In an embodiment of the present description, the gate dielectric 124 may include a high-k gate dielectric material, wherein the dielectric constant may comprise a value greater than about 4. Examples of high-k gate dielectric materials may include, but are not limited to, hafnium oxide, hafnium silicon oxide, lanthanum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium oxide, and lead zinc niobate.

The gate electronic 122 may include any appropriate conductive material. In one embodiment, the gate electrode 122 may comprise a metal, including, but not limited to, pure metal and alloys of titanium, tungsten, tantalum, aluminum, copper, ruthenium, cobalt, chromium, iron, palladium, molybdenum, manganese, vanadium, gold, silver, and niobium. Less conductive metal carbides, such as titanium carbide, zirconium carbide, tantalum carbide, tungsten carbide, and tungsten carbide, may also be used. The gate electrode 122 may also be made from a metal nitride, such as titanium nitride and tantalum nitride, or a conductive metal oxide, such as ruthenium oxide. The gate electrode 122 may also include alloys with rare earths, such as terbium and dysprosium, or noble metals such as platinum.

The dielectric spacers 126 may be made of any appropriate dielectric material. In one embodiment, the dielectric spacers 126 may comprise silicon dioxide, silicon oxy-nitride, or silicon nitride. In another embodiment, the dielectric spacers 126 may comprise a low-k dielectric material which may have a dielectric constant less than 3.6.

As shown in FIG. 2, an interlayer dielectric 130 may be formed on the microelectronic substrate 110 and over the transistor gate 120. The interlayer dielectric 130 may be any appropriate dielectric material, including, but not limited to, silicon dioxide, silicon nitride, and the like, and may be formed from a low-k (dielectric constant, k, such as 1.0-2.2) material that is formed by spin coating or chemical vapor deposition (CVD) of a material, such as organosilicate glass (OSG) or carbon-doped oxide (CDO).

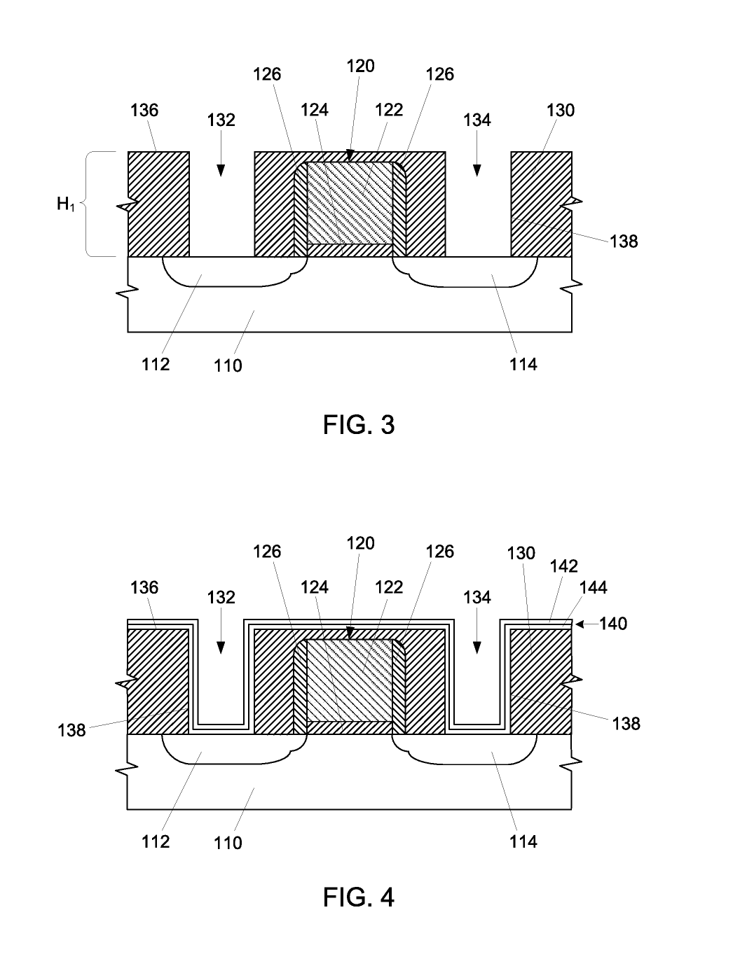

As shown in FIG. 3, at least one via (illustrated as first via 132 and second via 134) may be formed through the interlayer dielectric 130 from a first surface 136 of the interlayer dielectric 130 to the microelectronic substrate 110 forming at least one via sidewall 138 and exposing a portion of the microelectronic substrate 110. As illustrated, the first via 132 extends from the interlayer dielectric first surface 136 to the source region 112 and the second via 134 extends from the interlayer dielectric first surface 136 to the drain region 114. The vias, e.g. the first via 132 and the second via 134, may be formed by any technique known in the art, including, but not limited to, photolithography techniques, laser drilling, ion beam ablation, and the like.

As shown in FIG. 4, a contact material layer 140 may be formed adjacent the exposed portion of the microelectronic substrate 110 and the interlayer dielectric first surface 136. In one embodiment, wherein the contract material layer 140 is conformal, the contact material layer 140 may also be adjacent the at least one via sidewall 138. The contact material layer 140 may be any appropriate material which provides a more effective contact between the microelectronic substrate 110 and a subsequently deposited conductive material layer, than would result from direct contact therebetween, as will be understood to those skilled in the art. The contact material layer 140 may also prevent migration of the material of the subsequently formed contact into the microelectronic substrate 110, as will also be understood to those skilled in the art. In one embodiment, the contact material layer 140 may be multiple layers (illustrate as first layer 142 and second layer 144). In specific embodiment, the contact material first layer 142 may be titanium and the contact material second layer 144 may be titanium nitride. In an embodiment, wherein the contact material layer 140 is conformal, the contact material layer 140 may be deposited using any method well-known in the art to yield the conformal shape, such as, but not limited to, atomic layer deposition (ALD) and various implementations of chemical vapor deposition (CVD), such as atmospheric pressure CVD (APCVD), low pressure CVD (LPCVD), and plasma enhanced CVD (PECVD). In embodiments where the microelectronic substrate 110 is a three-dimensional fin structure, the contact material 140 is conformally deposited on the top surface as well as the two laterally opposing sidewall surfaces of the three-dimensional fin structure.

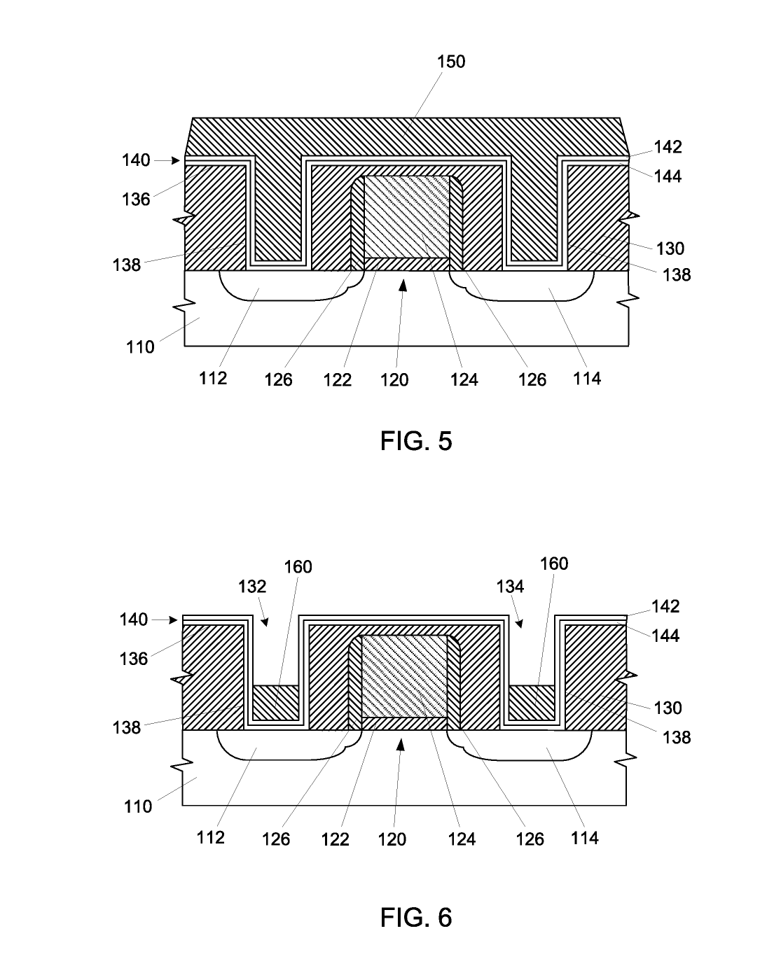

As shown in FIG. 5, an etch block material layer 150 may be deposited over the contact material layer 140 including into the first via 132 (see FIG. 4) and the second via 134 (see FIG. 4). In one embodiment, the etch block material layer 150 may comprise an amorphous carbon material, such as a carbon hard mask material used in photolithography, as known in the art. The etch block material layer 150 may be deposited by any known method known in the art, including, but not limited to, chemical vapor deposition, physical vapor deposition, and spin-on coating. In a specific embodiment, an amorphous carbon material may be deposited with a spin-on coating technique to form the etch block material layer 150. In embodiments where the microelectronic substrate 110 is a three-dimensional fin structure, the etch block material layer 150 is formed over the contact material layer 140 located on the top surface of the microelectronic substrate 110 and is formed adjacent to the contact material layer 140 located on the two laterally opposing sidewall surfaces of the three-dimensional fin structure.

As shown in FIG. 6, a portion of the etch block material layer 150 (see FIG. 5) may be removed by any known method to form etch block plugs 160 within the first via 132 and the second via 134, wherein the etch block plugs 160 are below the interlayer dielectric first surface 136 and are adjacent to the microelectronic substrate 110. In a specific embodiment, wherein the etch block material layer 150 (see FIG. 5) comprises an amorphous carbon material, the portion of the etch block material layer 150 (see FIG. 5) may be removed with a controlled plasma ashing process, as known in the art, to form the etch block plugs 160.

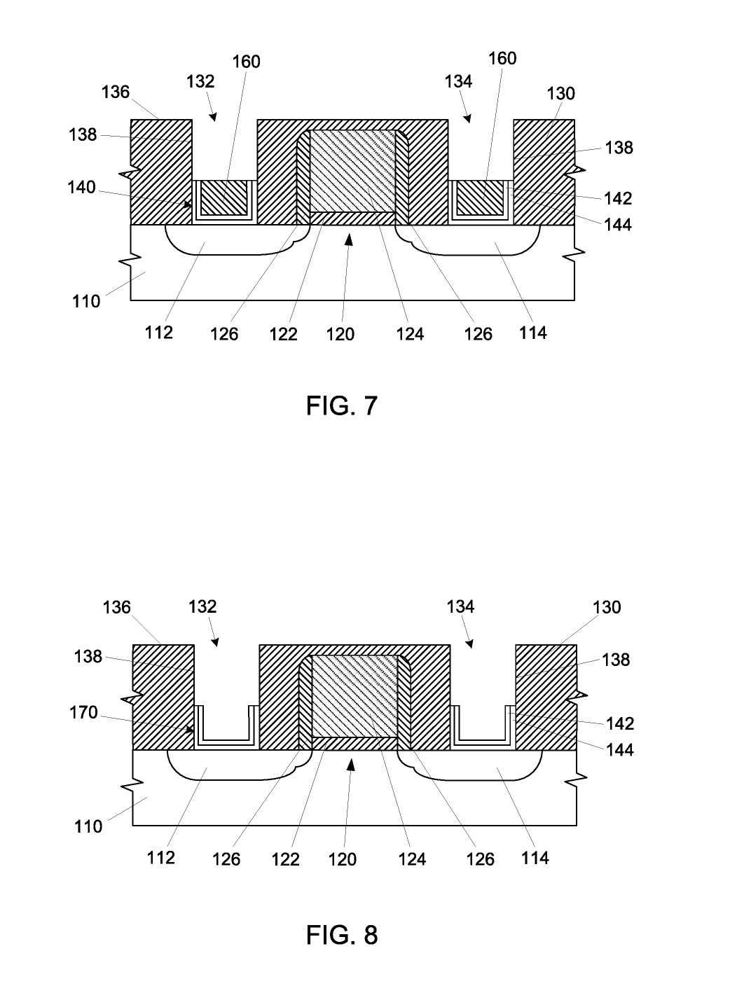

As shown in FIG. 7, a majority of the contact material layer 140 may be removed, such as by wet or dry etching, wherein the etch block plugs 160 protect a portion of the contact material layer 140 abutting the microelectronic substrate 110 from being. In an embodiment, wherein the contact material layer 140 is conformal, the etch block plugs 160 may also protect a portion of contact material layer 140 abutting at least one via sidewall 138 from being removed, as shown.

As shown in FIG. 8, the etch block plugs 160 may then be removed by any technique known in the art. In one embodiment where the etch block plugs 160 comprises an amorphous carbon material, the etch block plugs 160 may be removed with a plasma ashing process, as known in the art, to form a contact material structure 170. The contact material structure 170 may be a substantially “cup-shaped” structure or substantially “U-shaped” when viewed in side cross-section.

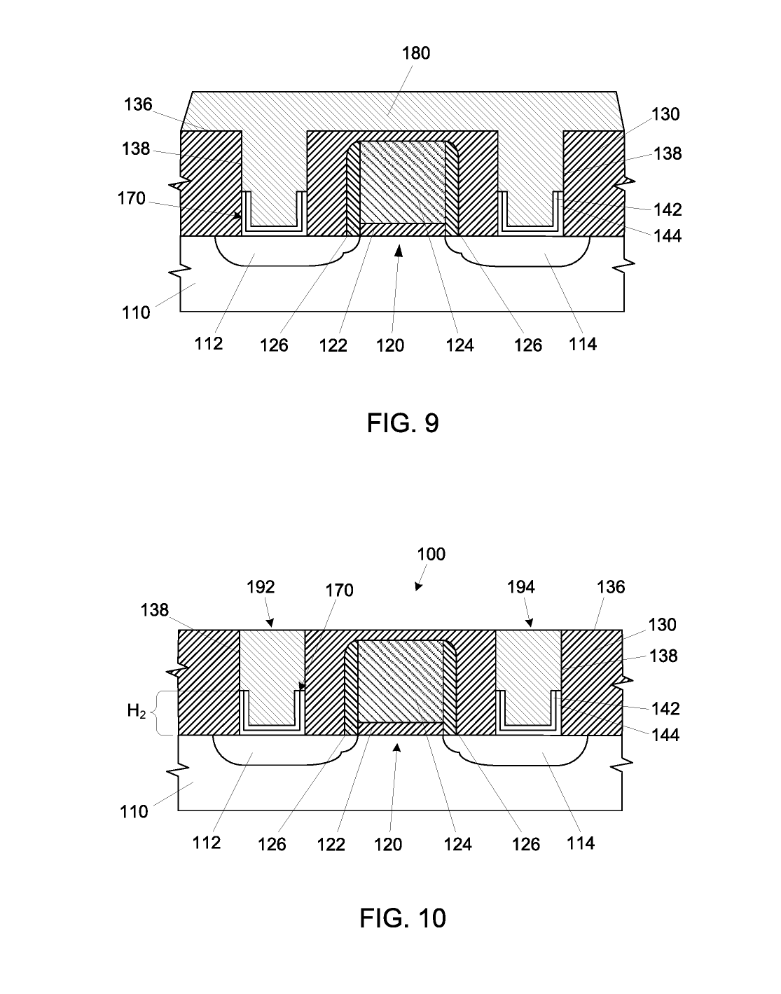

As shown in FIG. 9, a conductive material layer 180 may be deposited over the interlayer dielectric first surface 136 to fill the first via 132 (see FIG. 8) and the second via 134 (see FIG. 8). The conductive material layer 180 may be formed from any appropriate conductive material, such as a metallic material. In a specific embodiment, the conductive material layer 180 may comprise tungsten. The conductive material layer 180 may be deposited by any known method known in the art, including, but not limited to, chemical vapor deposition and physical vapor deposition. In embodiments where the microelectronic substrate 110 is a three-dimensional fin structure, the conductive material layer 180 is deposited over the contact material structure 170 located on the top surface of the microelectronic substrate 110 and is deposited adjacent to the contact material structure 170 located on the two laterally opposing sidewall surfaces of the three-dimensional fin structure.

As shown in FIG. 10, a portion of the conductive material layer 180 may be the removed to exposed the interlayer dielectric first surface 136 and forming individual contacts, shown as a first contact 192 proximate the source region 112 and a second contact 194 proximate the drain region 114. In one embodiment, as can be seen in FIG. 10, a portion of the contact material structure 170 abuts the at least one via sidewall 138 and may have a height H₂ which is less than 50% of a height H₁ (see FIG. 3) of the via (e.g. first via 132 of FIG. 3). In another embodiment, the portion of the contact material structure 170 abutting the at least one via sidewall 138 and may have a height H₂ which is between about 10% and 40% of the height H₁ (see FIG. 3) of the via (e.g. first via 132 of FIG. 3).

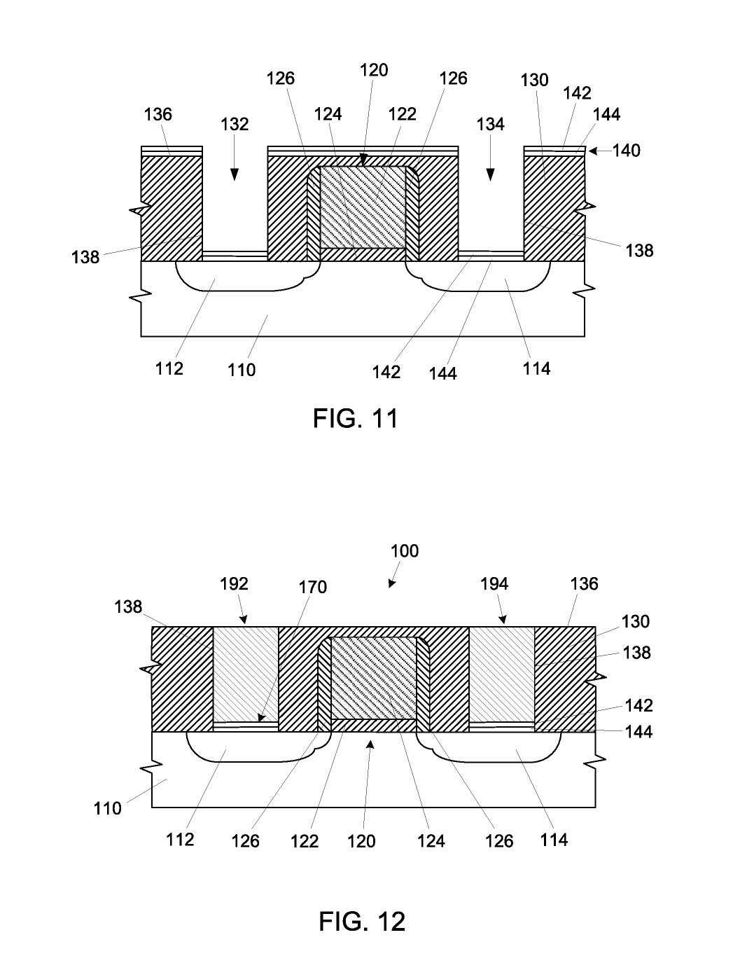

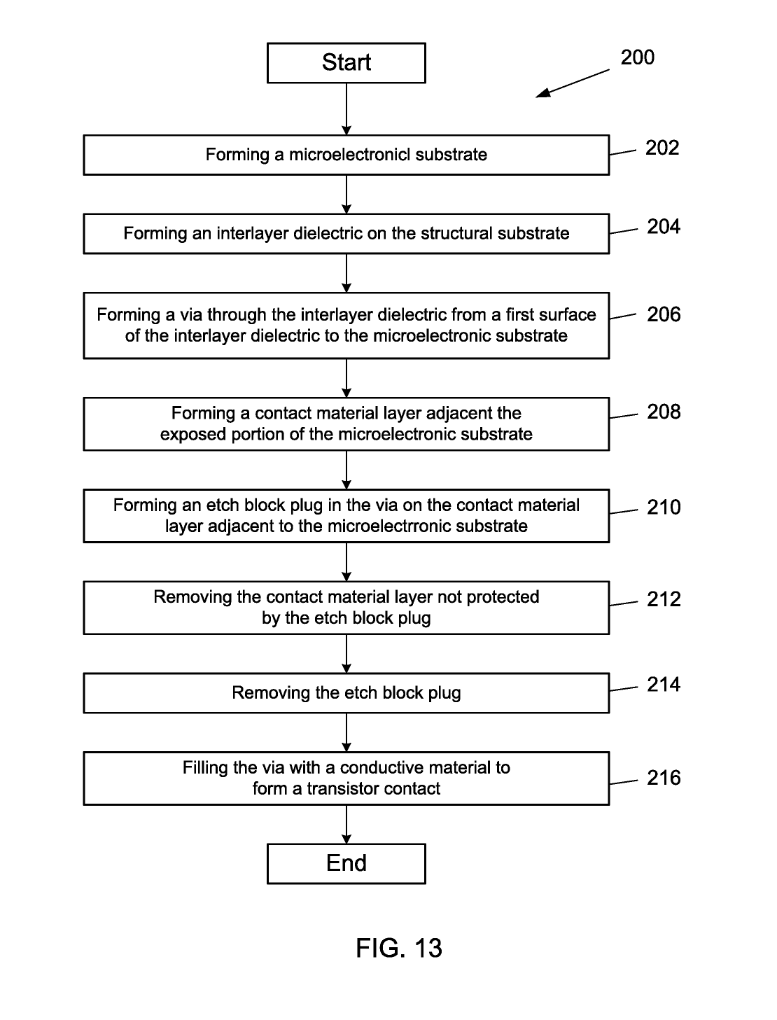

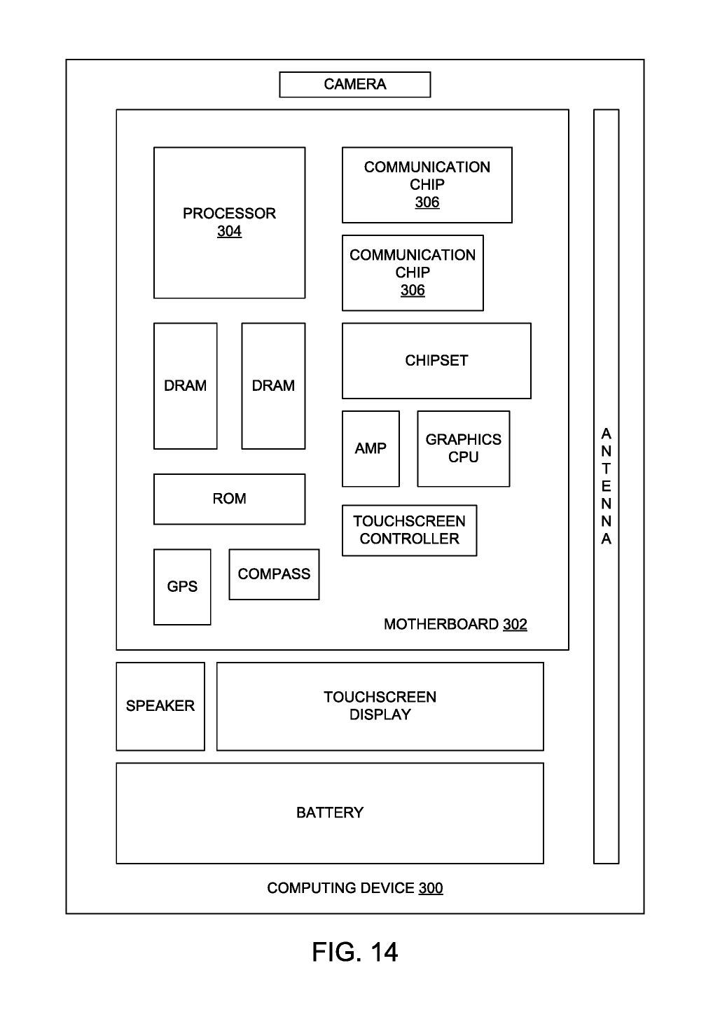

Although FIGS. 4-10 illustrates the contact material layer 140 as conformal, it is understood that the contact material layer 140 may be deposited non-conformally, as illustrated in FIG. 11 (analogous to FIG. 4). After following the steps described with regard to FIGS. 5-10, the resulting structure of a non-conformal contact material layer 140 is illustrated in FIG. 12 (analogous to FIG. 10).

In known methods, the contact material layer is left in place (such as shown in FIGS. 4 and 11), the conductive material is deposited into the vias, and the contact material layer abutting the interlay dielectric is removed in later processing. As will be understood to those skilled in the art, this known method puts constraints on material choices and downstream processing to ensure that the contact material layer abutting the interlayer dielectric first surface can be removed. Embodiments of the present description relaxes the constraints on material choices and on downstream processing, as the excess contact material layer is removed before any subsequent processing, such as thermal processing. Additionally, the embodiments of the present description remove more of the contact material layer than does the known method, which may result in a higher volume of conductive material within the via. As the conductive material is generally more highly conductive than the contact material layer, the resistance of the transistor contact is reduced, which may result in better performance of the microelectronic transistor.

FIG. 11 is a flow chart of a process 200 of fabricating a transistor structure according to an embodiment of the present description. As set forth in block 202, a microelectronic substrate may be formed. An interlayer dielectric may be formed on the microelectronic substrate, as set forth in block 204. As set forth in block 206, a via may be formed through the interlayer dielectric from a first surface of the interlayer dielectric to the microelectronic substrate forming a via sidewall and exposing a portion of the microelectronic substrate. A contact material layer may be formed adjacent the exposed portion of the microelectronic substrate, as set forth in block 208. As set forth in block 210, an etch block plug may be formed in the via on the contact material layer adjacent to the microelectronic substrate. The contact material layer not protected by the etch block plug may be removed, as set forth in block 212. As set forth in block 214, the etch block plug may be removed. The via may be filled with a conductive material to form a transistor contact, as set forth in block 216.

FIG. 12 illustrates a computing device 300 in accordance with one implementation of the present description. The computing device 300 houses a board 302. The board 302 may include a number of components, including but not limited to a processor 304 and at least one communication chip 306. The processor 304 is physically and electrically coupled to the board 302. In some implementations the at least one communication chip 306 is also physically and electrically coupled to the board 302. In further implementations, the communication chip 306 is part of the processor 304.

Depending on its applications, the computing device 300 may include other components that may or may not be physically and electrically coupled to the board 302. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 306 enables wireless communications for the transfer of data to and from the computing device 300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 306 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 300 may include a plurality of communication chips 306. For instance, a first communication chip 306 may be dedicated to shorter range wireless communications such as Wi-Fi and Bluetooth and a second communication chip 306 may be dedicated to longer range wireless communications such as GPS, EDGE, GPRS, CDMA, WiMAX, LTE, Ev-DO, and others.

The processor 304 of the computing device 300 includes an integrated circuit die packaged within the processor 304. In some implementations of the present description, the integrated circuit die of the processor includes one or more devices, such as nanowire transistors built in accordance with implementations of the present description. The term “processor” may refer to any device or portion of a device that processes electronic data from registers and/or memory to transform that electronic data into other electronic data that may be stored in registers and/or memory.

The communication chip 306 also includes an integrated circuit die packaged within the communication chip 306. In accordance with another implementation of the present description, the integrated circuit die of the communication chip includes one or more contacts in accordance with embodiments of the present description.

In further implementations, another component housed within the computing device 300 may contain an integrated circuit die that includes one or more contact in accordance with embodiments of the present description.

In various implementations, the computing device 300 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 300 may be any other electronic device that processes data.

It is understood that the subject matter of the present description is not necessarily limited to specific applications illustrated in FIGS. 1-12. The subject matter may be applied to other microelectronic device and assembly applications, as well as any appropriate transistor application, as will be understood to those skilled in the art.

The following examples pertain to further embodiments, wherein Example 1 is a method of forming a transistor contact, comprising: forming a via through an interlayer dielectric layer disposed on a microelectronic substrate, wherein the via extends from a first surface of the interlayer dielectric layer to the microelectronic substrate forming a via sidewall and exposing a portion of the microelectronic substrate; forming a contact material layer adjacent the exposed portion of the microelectronic substrate, the at least one via sidewall, and the interlayer dielectric first surface; forming an etch block plug within the via proximate the microelectronic substrate; removing the contact material layer not protected by the etch block plug forming a contact material structure; removing the etch block plug; and filling the via with a conductive material.

In Example 2, the subject matter of Example 1 can optionally include forming the etch block plug comprising forming an amorphous carbon etch block plug.

In Example 3, the subject matter of any of Examples 1 to 2 can optionally include forming of the etch block plug comprising depositing an etch block material layer over the conformal contact material layer including into the via and removing a portion of the etch block material.

In Example 4, the subject matter of Example 3 can optionally include depositing the etch block material layer comprising depositing an amorphous carbon material layer.

In Example 5, the subject matter of any of Examples 1 to 4 can optionally include forming the conformal contact material layer comprising forming a multilayer conformal contact material layer.

In Example 6, the subject matter of Example 5 can optionally include forming the multilayer conformal contact material layer comprising forming a conformal titanium layer adjacent the exposed portion of the microelectronic substrate, the at least one via sidewall, and the interlayer dielectric first surface and forming a conformal titanium nitride layer on the conformal titanium layer.

In Example 7, the subject matter of any of Examples 1 to 6 can optionally include forming the contact material layer comprising forming a conformal contact layer abutting the exposed portion of the microelectronic substrate, the at least one via sidewall, and the interlayer dielectric first surface.

In Example 8, the subject matter of any of Examples 1 to 7 can optionally include removing the contact material layer not protected by the etch block plug forming the contact material structure comprising removing the conformal contact material layer not protected by the etch block plug which forms a portion of the conformal contact material structure abutting the at least one via sidewall having a height less than 50% of a height of the via.

In Example 9, the subject matter of any of Examples 1 to 7 can optionally include removing the conformal contact material layer not protected by the etch block plug the contact material structure comprising removing the conformal contact material layer not protected by the etch block plug which forms a portion of the conformal contact material structure abutting the at least one via sidewall having a height between about 10% and 40% of a height of the via.

In Example 10, the subject matter of any of Examples 1 to 9 can optionally include filling the via with a conductive material comprising filling the via with tungsten.

In Example 11, the subject matter of any of Examples 1 to 10 can optionally include forming the microelectronic substrate having at least one of a source region and a drain region and wherein forming the via comprises forming a via through the interlayer dielectric layer from a first surface of the interlayer dielectric layer to the microelectronic substrate forming a via sidewall and exposing a portion of at least one of the source region and the drain region.

The following examples pertain to further embodiments, wherein Example 12 is a microelectronic structure, comprising: a microelectronic substrate; an interlayer dielectric layer on the microelectronic substrate; a via through the interlayer dielectric layer from a first surface of the interlayer dielectric layer to the microelectronic substrate, wherein the via includes at least one via sidewall; a contact material structure within the via, wherein the contact material structure comprises a conformal layer having a portion abutting the microelectronic substrate and a portion abutting the at least one via sidewall without extending an entire height of the via; and a conductive material abutting the contact material structure.

In Example 13, the subject matter of any of Example 12 can optionally include the contact material structure comprising a multilayer contact material structure.

In Example 14, the subject matter of Example 12 can optionally include the multilayer contact material structure comprising a titanium layer abutting the microelectronic substrate and a titanium nitride layer on the titanium layer.

In Example 15, the subject matter of any of Examples 12 to 14 can optionally include a portion of the contact material structure abutting the at least one via sidewall having a height less than 50% of a height of the via.

In Example 16, the subject matter of any of Examples 12 to 15 can optionally include a portion of the contact material structure abutting the at least one via sidewall having a height between about 10% and 40% of a height of the via.

In Example 17, the subject matter of any of Examples 12 to 16 can optionally include the microelectronic substrate comprising a three-dimensional fin structure having a top surface and two laterally opposing sidewall surfaces.

In Example 18, the subject matter of any of Examples 12 to 17 can optionally include the contact material structure being substantially U-shaped in side cross-section.

In Example 19, the subject matter of any of Examples 12 to 18 can optionally include the conductive material comprising tungsten.

In Example 20, the subject matter of any of Examples 12 to 19 can optionally include the contact material structure contacting at least one of a source region and drain region formed in the microelectronic substrate.

The following examples pertain to further embodiments, wherein Example 21 is a microelectronic structure, comprising: a computing device, comprising: a microelectronic board having at least one of a processor and a communication chip electrically coupled thereto; wherein the at least one of the processor and the communication chip includes at least one microelectronic transistor; and wherein the microelectronic transistor includes at least one microelectronic structure comprising: an interlayer dielectric layer on the microelectronic substrate; a via through the interlayer dielectric layer from a first surface of the interlayer dielectric layer to the microelectronic substrate, wherein the via includes at least one via sidewall; a contact material structure within the via, wherein the contact material structure comprises a conformal layer having a portion abutting the microelectronic substrate and the at least one via sidewall without extending an entire height of the via; and a conductive material abutting the contact material structure.

In Example 22, the subject matter of Example 21 can optionally include a portion of the contact material structure abutting the at least one via sidewall has a height less than 50% of a height of the via.

In Example 23, the subject matter of Example 21 can optionally include a portion of the contact material structure abutting the at least one via sidewall has a height between about 10% and 40% of a height of the via.

In Example 24, the subject matter of any of Examples 21 to 23 can optionally include the microelectronic substrate comprising a three-dimensional fin structure having a top surface and two laterally opposing sidewall surfaces.

In Example 25, the subject matter of any of Examples 21 to 24 can optionally include the contact material structure being substantially U-shaped in side cross-section.

Having thus described in detail embodiments of the present description, it is understood that the present description defined by the appended claims is not to be limited by particular details set forth in the above description, as many apparent variations thereof are possible without departing from the spirit or scope thereof.

1.-25. (canceled)

26. A method of forming a transistor contact, comprising:
forming a via through an interlayer dielectric layer disposed on a microelectronic substrate, wherein the via extends from a first surface of the interlayer dielectric layer to the microelectronic substrate forming a via sidewall and exposing a portion of the microelectronic substrate;
forming a contact material layer adjacent the exposed portion of the microelectronic substrate;
forming an etch block plug within the via proximate the microelectronic substrate;
removing the contact material layer not protected by the etch block plug forming a contact material structure;
removing the etch block plug; and
filling the via with a conductive material.

27. The method of claim 26, wherein forming the etch block plug comprises forming an amorphous carbon etch block plug.

28. The method of claim 26, wherein forming the etch block plug comprises depositing an etch block material layer over the contact material layer including into the via and removing a portion of the etch block material.

29. The method of claim 28, wherein depositing the etch block material layer comprises depositing an amorphous carbon material layer.

30. The method of claim 26, wherein forming the contact material layer comprises forming a multilayer contact material layer.

31. The method of claim 30, wherein forming the multilayer contact material layer comprises forming a titanium layer adjacent the exposed portion of the microelectronic substrate and the interlayer dielectric first surface and forming a titanium nitride layer on the titanium layer.

32. The method of claim 26, wherein forming the contact material layer comprises forming a conformal contact layer abutting the exposed portion of the microelectronic substrate, the at least one via sidewall, and the interlayer dielectric first surface.

33. The method of claim 32, wherein removing the conformal contact material layer not protected by the etch block plug forming the contact material structure comprises removing the conformal contact material layer not protected by the etch block plug which forms a portion of the conformal contact material structure abutting the at least one via sidewall having a height less than 50% of a height of the via.

34. The method of claim 32, wherein removing the conformal contact material layer not protected by the etch block plug forming the contact material structure comprises removing the conformal contact material layer not protected by the etch block plug which forms a portion of the conformal contact material structure abutting the at least one via sidewall having a height between about 10% and 40% of a height of the via.

35. The method of claim 26, wherein filling the via with a conductive material comprises filling the via with tungsten.

36. The method of claim 26, wherein forming the microelectronic substrate comprises forming a microelectronic substrate having at least one of a source region and a drain region and wherein forming the via comprises forming a via through the interlayer dielectric layer from a first surface of the interlayer dielectric layer to the microelectronic substrate forming a via sidewall and exposing a portion of at least one of the source region and the drain region.

37. A microelectronic structure, comprising:
a microelectronic substrate;
an interlayer dielectric layer on the microelectronic substrate;
a via through the interlayer dielectric layer from a first surface of the interlayer dielectric layer to the microelectronic substrate, wherein the via includes at least one via sidewall;
a contact material structure within the via, wherein the contact material structure comprises a conformal layer having a portion abutting the microelectronic substrate and a portion abutting the at least one via sidewall without extending an entire height of the via; and
a conductive material abutting the contact material structure.

38. The microelectronic structure of claim 37, wherein the contact material structure comprises a multilayer contact material structure.

39. The microelectronic structure of claim 38, wherein the multilayer contact material structure comprises a titanium layer abutting the microelectronic substrate and a titanium nitride layer on the titanium layer.

40. The microelectronic structure of claim 37, wherein the portion of the contact material structure abutting the at least one via sidewall has a height less than 50% of a height of the via.

41. The microelectronic structure of claim 37, wherein the portion of the contact material structure abutting the at least one via sidewall has a height between about 10% and 40% of a height of the via.

42. The microelectronic structure of claim 37, wherein the microelectronic substrate comprises a three-dimensional fin structure having a top surface and two laterally opposing sidewall surfaces.

43. The microelectronic structure of claim 37, wherein the contact material structure is substantially U-shaped in side cross-section.

44. The microelectronic structure of claim 37, wherein the conductive material comprises tungsten.

45. The microelectronic structure of claim 37, wherein the contact material structure contacts at least one of a source region and drain region formed in the microelectronic substrate.

46. A computing device, comprising:
a board having at least one of a processor and a communication chip electrically coupled thereto;
wherein the at least one of the processor and the communication chip includes at least one microelectronic transistor; and
wherein the microelectronic transistor includes at least one microelectronic structure comprising:
an interlayer dielectric layer on a microelectronic substrate;
a via through the interlayer dielectric layer from a first surface of the interlayer dielectric layer to the microelectronic substrate, wherein the via includes at least one via sidewall;
a contact material structure within the via, wherein the contact material structure comprises a conformal layer having a portion abutting the microelectronic substrate and a portion abutting the at least one via sidewall without extending an entire height of the via; and
a conductive material abutting the contact material structure.

47. The computing device of claim 46, wherein a portion of the contact material structure abutting the at least one via sidewall has a height less than 50% of a height of the via.

48. The computing device of claim 46, wherein a portion of the contact material structure abutting the at least one via sidewall has a height between about 10% and 40% of a height of the via.

49. The computing device of claim 46, wherein the microelectronic substrate comprises a three-dimensional fin structure having a top surface and two laterally opposing sidewall surfaces.

50. The computing device of claim 46, wherein the contact material structure is substantially U-shaped in side cross-section.
